(19) United States
(12) Patent Application Publication
(10) Pub. No.: US 2024/0327694 A1
(43) Pub. Date: Oct. 3, 2024

(54) HEAT-TRANSFER LIQUID SOLUTION, AND RELATED METHODS OF MAKING AND USING

(71) Applicant: Seagate Technology LLC, Fremont, CA (US)

(72) Inventors: Li Hong Zhang, Singapore (SG); Barish Chakravarty, Ang Mo Kio (SG); Xiong Liu, Singapore (SG); Swee Chuan Gan, Singapore (SG)

(21) Appl. No.: 18/616,486

(22) Filed: Mar. 26, 2024

Related U.S. Application Data
(60) Provisional application No. 63/456,142, filed on Mar. 31, 2023.

(51) Int. Cl. C09K 5/10; H05K 7/20

(52) U.S. Cl. CPC C09K 5/10; H05K 7/20236; H05K 7/20818

(57) ABSTRACT

The present disclosure includes methods of making a heat-transfer liquid solution by combining a heat-transfer liquid with a solute component to form a heat-transfer liquid solution, and related heat-transfer liquid solutions and methods of using.

### CROSS-REFERENCE TO RELATED APPLICATIONS

This application claims the benefit of U.S. Provisional Patent Application having Ser. No. 63/456,142 titled “HEAT-TRANSFER LIQUID SOLUTION, AND RELATED METHODS OF MAKING AND USING” filed Mar. 31, 2023, the entire contents of which are incorporated by reference for all purposes herein.

### BACKGROUND

The present disclosure relates to heat-transfer liquids (coolants) for liquid immersion cooling systems for electronic data storage devices (e.g., HDDs), e.g., data centers having large numbers of such devices. There is a continuing need to improve heat-transfer liquids and related methods of making and using.

### SUMMARY

The present disclosure includes embodiments of a method of making a heat-transfer liquid solution, wherein the method includes:
providing a heat-transfer liquid including a solvent component, wherein the solvent component includes one or more solvents, and wherein each solvent has a dielectric constant;
combining the heat-transfer liquid with a solute component to form a heat-transfer liquid solution, wherein the solute component includes one or more solutes, and wherein each solute has a dielectric constant, and wherein the heat-transfer liquid solution has a dielectric constant of 7.5 or less at a frequency of 1 khz and a temperature in a range from 0° C. to 60° C.

The present disclosure also includes embodiments of a method of making a heat-transfer liquid solution, wherein the method includes.
providing a heat-transfer liquid including a solvent component, wherein the solvent component includes one or more solvents, and wherein each solvent has a dielectric constant;
combining the heat-transfer liquid with a solute component to form a heat-transfer liquid solution, wherein the solute component includes one or more solutes, and wherein each solute is present in an amount of greater than 20% saturation at one or more operating temperatures of a system configured to immerse a data storage device in the heat-transfer liquid solution.

The present disclosure also includes embodiments of heat transfer liquid solution including:
a solvent component including one or more solvents;
a solute component including one or more solutes, wherein the one or more solutes are chosen from polypropylene (PP), polyamide, polyethylene terephthalate, polyisoprene, one or more siloxanes, and combinations thereof.

### BRIEF DESCRIPTION OF THE DRAWINGS

FIG. 1 is a table of materials of extracted into a heat-transfer liquid after submerging hard disk drives in the heat-transfer liquid in an immersion cooling system;

FIG. 2 is a graph showing failure rate different heat-transfer solvents;

FIG. 3 is a schematic illustrating “pre-existing” solutes in a heat-transfer liquid solution according to the present disclosure;

FIG. 4 is a table of illustrating “pre-existing” solutes and corresponding dielectric constants; and

FIG. 5 is a schematic embodiment of an immersion cooling system.

### DETAILED DESCRIPTION

The present disclosure relates to heat-transfer liquids (coolants) for liquid immersion cooling systems for electronic data storage devices (e.g., HDDs), e.g., data centers having large numbers of such devices.

Immersion cooling with an immersion-cooling system is a cooling technique in which electronic data storage devices (e.g., sealed hard disk drives) are fully submerged in a heat-transfer liquid (liquid coolant) that is thermally conductive and also electrically insulating. Heat is removed from the immersion-cooling system by putting the heat-transfer liquid in direct contact with electronic data storage devices, and circulating the heated heat-transfer liquid through one or more heat-exchangers. This technique is highly effective because heat-transfer liquid can absorb more heat from the immersion-cooling system, and is more easily circulated through the system as compared to air.

Unlike many other devices, electronic data storage devices cannot use water cooling because water is a good solvent to many electrically conductive materials so it can become electrically conductive, which can cause electronic data storage devices to break down. Therefore, heat-transfer liquids used in immersion cooling are dielectric liquids so that heat-transfer liquids can come into safe contact with energized cause electronic data storage devices.

As discussed in detail below, according to the present disclosure a heat-transfer liquid is combined with a solute component to form a heat-transfer liquid solution with a “pre-existing” solute prior to use in an immersion-cooling system. As used herein, a “heat-transfer liquid” is also referred to a solvent component that includes one or more solvents because one or more solutes are dissolved in a heat-transfer liquid/solvent component to form a heat-transfer liquid solution. As discussed below, a heat-transfer liquid solution is made up mostly of the solvent component. While a solvent component can include a mixture of two or more different solvents, in some embodiments a solvent component includes only one solvent.

A solvent for use a heat-transfer liquid can be selected based on one or more of its electrical properties, physical properties, and chemical properties.

Non-limiting of useful electrical properties to consider include dielectric constant, volume resistivity, and the like.

The dielectric constant of a solvent in the solvent component can be selected so that the solvent sufficiently functions as an electrical insulator when it is in contact with a submerged electrical component that is energized. A data storage device such a hard disk drive includes electrical features such a printed circuit board, electrical connectors, and the like that are submerged and in contact with a heat-transfer liquid while cooling. In some embodiments, the solvent component has a dielectric constant of 7.5 or less, 5 or less, 4 or less, 3 or less, or even 2.5 or less. If desired, the dielectric constant specification of one or more solvents can be determined experimentally through a reliability read/write test in a single-phase immersion cooling system, during which, the hard disk drives (HDDs) should not give soft errors within the designed read/write frequency range.

The dielectric constant of a solvent in the solvent component is a function of both temperature and frequency. The temperature of interest can depend on the operating temperature of the data storage device while it is energized and/or the set point that the heat-transfer liquid solution is controlled to in the immersion-cooling system. In some embodiments, the dielectric constant of a solvent is selected for a temperature in a range from 0° C. to 60° C., or even from 5° C. to 60° C. The frequency of interest can depend on one or more sources of electric fields present in a data storage device and/or the immersion-cooling system. Non-limiting examples of sources of electric fields include write/read fields in a hard disk drive, the electric signal of transferring data between a system circuit board and data storage devices, etc. In some embodiments, the dielectric constant of the solvent component is selected for a frequency of 1 khz. In some embodiments, if a solvent component includes two or more solvents, each solvent can have a dielectric constant that meets the above criteria.

In some embodiments, a solvent can also be selected based on its volume resistivity, which is a measure of how strongly the solvent opposes the flow of electric current while it functions as a heat-transfer liquid during cooling. In some embodiments, the solvent component has a volume resistivity 1×10⁸ ohm-m at 25° C. or more, 1×10⁹ ohm-m at 25° C. or more, or even 1×10¹⁰ ohm-m at 25° C. or more. In some embodiments, if a solvent component includes two or more solvents, each solvent can have a volume resistivity that meets the above criteria.

A heat-transfer liquid solution according to the present disclosure is selected to be a “single-phase” heat-transfer liquid solution, which means that the electronic data storage devices are fully submerged in the heat-transfer liquid solution while the heat-transfer liquid solution cools the energized electronic data storage devices without the heat-transfer liquid solution changing phase (e.g., from liquid to gas) under normal operating temperatures of the energized electronic data storage devices and immersion-cooling system. For example, a single-phase heat transfer liquid solution can have a boiling point that is greater than the highest operating temperature of the energized electronic data storage devices, which may reach 70° C. So, in some embodiments, the solvent component and solute component can be selected so that the heat-transfer liquid solution has a boiling point of greater than 70° C. For example, a heat-transfer liquid solution can have a boiling point of 80° C. or greater, 90° C. or greater, 100° C. or greater, 110° C. or greater, 120° C. or greater, 150° C. or greater, or even 200° C. or greater. In some embodiments, the solvent component and solute component can be selected so that the heat-transfer liquid solution has a boiling point that is at least 30° C. greater than the highest operating temperature of the energized electronic data storage devices.

Also, a solvent can be selected so that chemical breakdown of the solvent does occur to an undue degree while the solvent is in contact with the energized electronic data storage devices and immersion-cooling system under normal operating temperatures.

In some embodiments, a solvent can also be selected based on its Hildebrand Solubility Parameter (HSP), which is a good measure of the solubility of a solvent to one or more solutes that may be selected for making a heat-transfer liquid solution according to the present disclosure, especially for non-polar and/or slightly polar solvents. The Hildebrand Solubility Parameter of a solvent can be described by the following equation:

$$H S P = {( ( Δ {H}_{v} - RT ) / ( {V}_{m} ) )}^{1 / 2}$$

where ΔHᵥ is the heat of evaporation (related to intermolecular forces), R the gas constant, T the temperature, and Vₘ the molar volume.

In some embodiments, one or more solvents have a Hildebrand Solubility Parameter of 16 or more, 16.5 or more, 17 or more, 18 or more, 19 or more, 20 or more, 25 or more, or even 30 or more.

A variety of solvents having suitable heat-transfer properties, chemical properties, and electrical properties can be used in a solvent component of a heat-transfer liquid solution according to the present disclosure. In some embodiments, a solvent component includes one or more solvents chosen from one or more hydrocarbon solvents, one or more fluorocarbon solvents, one or more hydrofluorocarbon solvents, and combinations thereof. In some embodiments, a solvent component includes one or more solvents chosen from one or more hydrocarbon solvents. In some embodiments, a solvent component includes one or more solvents chosen from one or more fluorocarbon solvents, one or more hydrofluorocarbon solvents, and combinations thereof, since fluorocarbon solvents tend to mix relatively well with hydrofluorocarbon solvents. Non-limiting examples of solvents include at least one natural oil, at least one synthetic oil, at least one fluoro-octane, at least one hydrofluoroether, at least one hydrofluorolefin, at least one perfluoroketone, at least one perfluoropolyether, at least one perfluorocarbon, and mixtures thereof. In some embodiments, a solvent component can include one or more solvents chosen from perfluoro (2-methyl-3-pentanone), methoxy-nonafluorobutane, hydrofluoroether, perfluorohexane, 1-methoxyheptafluoropropane, mineral oil, white oil, synthetic saturated hydrocarbons with carbon atoms ranging from 12 to 60, and combinations thereof. A non-limiting example of a solvent for use as a heat-transfer liquid is commercially available under the tradename Novec™ 649 Engineered Fluid from 3M™. In some embodiments, a solvent component includes one or more hydrocarbon solvents. A non-limiting example includes at least one natural oil and at least one synthetic oil. In some embodiments, a solvent component includes one or more solvents chosen from one or more fluorocarbon solvents, one or more hydrofluorocarbon solvents, and combinations thereof, since fluorocarbon solvents tend to mix relatively well with hydrofluorocarbon solvents. A non-limiting example includes at least one fluoro-octane, at least one hydrofluoroether, at least one hydrofluorolefin, at least one perfluoroketone, at least one perfluoropolyether, at least one perfluorocarbon, and mixtures thereof.

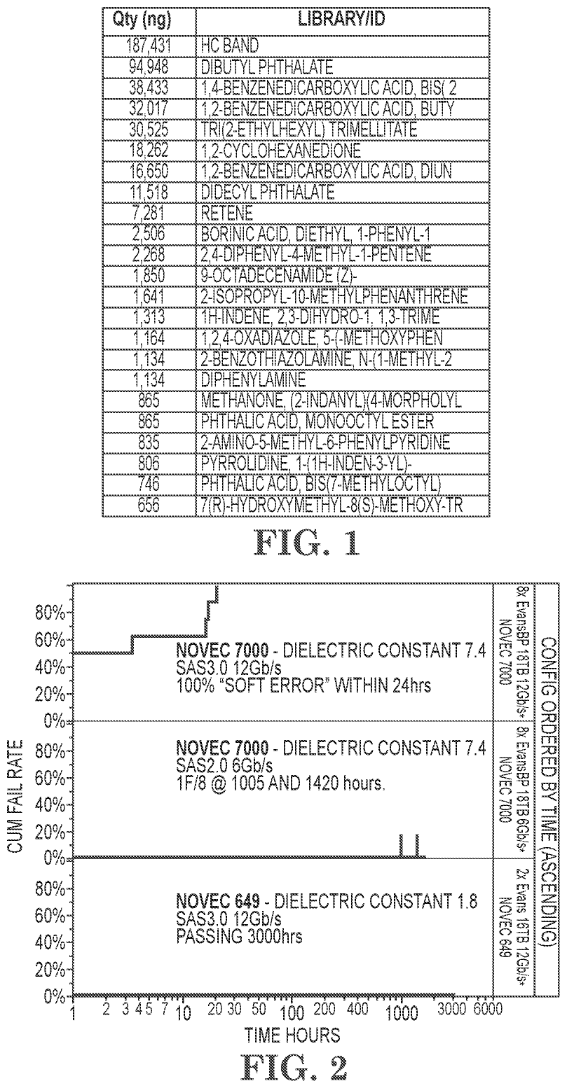

Immersion cooling of electronic data storage devices with a solvent as a heat-transfer liquid in an immersion-cooling system has one or more potential benefits as compared to air cooling such as shorter test time, lower power consumption, and relatively higher areal density capacity (ADC) for sealed hard disk drives. However, a heat-transfer liquid can extract (dissolve) one or more materials, which form “extracted materials”, from the electronic data storage devices and/or immersion cooling equipment that is in contact with the heat-transfer liquid. In such cases, or more of the benefits mentioned above may be hard realize if the heat-transfer liquid (solvent component) is contaminated to an undue degree with extracted materials due to the dissolution of one or more materials in contact with the heat-transfer liquid. In more detail, one or more heat-transfer liquids (e.g., engineered coolants) discussed above for immersion cooling may have a chemically affinity to materials such as non-polar and/or slightly polar chemicals, and therefore, have a degree of solubility with respect to chemicals such as hydrocarbons, plasticizers, silicone, etc. Such chemicals may be present in electronic data storage devices (e.g., sealed disk drives) that are submerged in the heat-transfer liquid during cooling and/or present in one or more features of an immersion-cooling system that is in contact with the heat-transfer liquid. At least a portion of one or more chemicals that are soluble in the heat-transfer liquid may be extracted (dissolved) from the component they are present into the heat-transfer liquid. For illustration purposes, FIG. 1 shows GC-MS analysis data for the main compounds in Novec™ 7000 coolant after immersion test for HDDs for six months. As shown in FIG. 1, a hydrofluoroether (HFE) heat-transfer liquid (coolant) can dissolve materials (that results in extracted materials) such as sealing compounds, elastomers, plasticizers, hydrocarbons which can come from the labels, thermal interface material (TIM), hoses/pipes/O-rings, solder flux, etc. from immersion-cooling system. Many of these extracted materials/chemicals are present in plastics as the base material or the additives. TIM is a high heat conductive material that can be inserted between a heat-sink and an electronic device to improve the thermal transfer to the heat-sink. For example, in a hard disk drive a TIM can be inserted between the SOC chip and the hard disk drive base to direct heat from the SOC to the base, which is the heatsink.

Contamination of a heat-transfer liquid by such extracted materials can degrade one or more electrical and/or chemical properties of the heat-transfer liquid, which may change, e.g., the resistivity and dielectric constant of the heat-transfer liquid. The changes may affect the performance of the electronic circuits of the electronic devices submerged in the heat-transfer liquid during cooling by changing the signal integrity such as error rates, bandwidth, leakage current, gain etc. For illustration purposes, such changes in the electrical properties of a heat-transfer liquid can cause read/write errors in a hard disk drive, especially during high-frequency operations. FIG. 2 shows an example of a much higher failure rate of hard disk drives immersed in Novec™ 7000 Engineered Fluid than in Novec™ 649 Engineered Fluid, each of which have a different dielectric constant.

Contamination of a heat-transfer liquid by such extracted materials can degrade one or more functional and/or structural characteristic of the component that they were extracted from. For example, chemicals that are extracted from a component can cause the component (e.g., equipment parts such as hoses, etc.) to change shape, which may cause the component to malfunction.

According to the present disclosure, one or more solutes are added to one or more heat-transfer solvents liquid as “pre-existing” solutes prior to use to form a heat-transfer liquid solution.

In some embodiments, the one or more solutes may the same as one or more of the “extracted” materials as long as such solutes do not impact the properties of the heat-transfer liquid solution to an undue degree. In such embodiments, the pre-existing solutes tend to at least inhibit mass transfer of the same materials from the electronic data storage devices and/or immersion cooling equipment so that the function of the electronic data storage devices and/or immersion cooling equipment is not impacted.

In some embodiments, the one or more solutes may be different from the “extracted” materials and may be selected based on desirable properties similar to the solvent component. In such embodiments, the pre-existing solutes tend to inhibit mass transfer of materials from the electronic data storage devices and/or immersion cooling equipment that may compromise one or more properties of the solvent component in addition to the function of the electronic data storage devices and/or immersion cooling equipment.

A solute component includes one or more solutes that are compatible with a solvent component and help mitigate or prevent the mass transfer of materials from an electronic data storage device and/or immersion cooling equipment that are in contact with the solvent component.

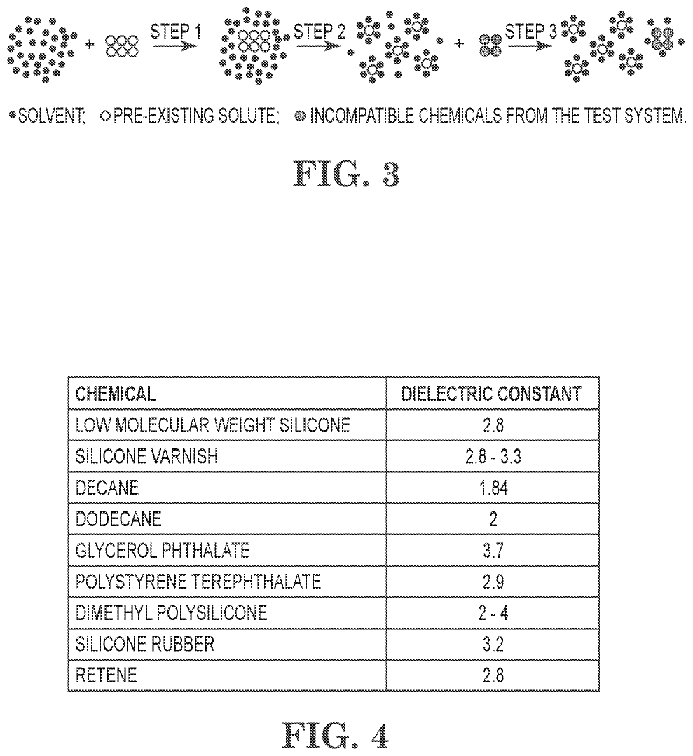

For illustration purposes, an example of forming a heat-transfer liquid solution with a pre-existing solute component is described with respect to FIG. 3. In step 1, a heat-transfer liquid solution is formed by dissolving a single solute component into a single solvent, which may be a non-polar or slightly polar solvent. After dissolving the solute into the solvent, the pre-existing solute molecules in the heat-transfer liquid solution break the intermolecular forces of the solvent so that the pre-existing solute molecules form clusters (shown after step 2) with the solvent molecules via solvent-solute intermolecular interactions. For the solvent and pre-existing solute, the solubility of the solvent to subsequent solutes will be reduced, assuming the subsequent solutes have comparable or less affinity to the solvent than the pre-existing solute, which can be selected as described herein. In some embodiments, when the pre-existing solute is at the saturated level, the solvent's capability to dissolve other solutes can be minimized.

One or more solutes can be selected based one or more factors including compatibility with the solvent component as well as one or more factors discussed above with respect to selecting a solvent.

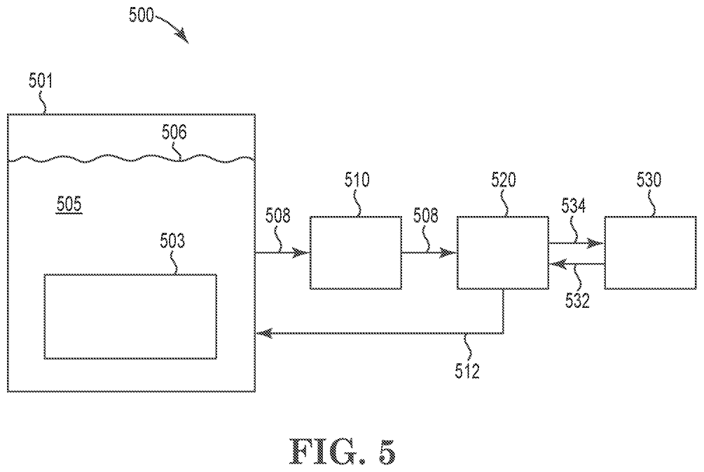

The dielectric constant of one or more solutes in the solute component can be selected so that it does not cause the heat-transfer liquid solution to be out of specification with respect to its dielectric constant. As discussed below, the specification of the heat-transfer liquid solution is considered the same as that discussed above with respect to the solvent component. In some embodiments, the dielectric constant of one or more solutes may be greater than the dielectric constant of the solvent component. In some embodiments, the dielectric constant of one or more solutes may be the same or less than the dielectric constant of the solvent component. In some embodiments, one or more solutes have a dielectric constant of 7.5 or less, 5 or less, 4 or less, 3 or less, or even 2.5 or less at a frequency of 1 khz and at a temperature in a range from 0° C. to 60° C. (e.g., from 5° C. to 60° C.)). For illustration purposes, FIG. 4 is a non-limiting list of chemicals that can be used as a preexisting solute and their dielectric constants. FIG. 4 includes examples of pre-existing solutes that may or may not be the same as extracted materials discussed above.

The volume resistivity of one or more solutes in the solute component can be selected so that it does not cause the heat-transfer liquid solution to be out of specification with respect to its volume resistivity. As discussed below, the specification of the heat-transfer liquid solution is considered the same as that discussed above with respect to the solvent component. In some embodiments, the volume resistivity of one or more solutes may be greater than the dielectric constant of the solvent component. In some embodiments, the volume resistivity of one or more solutes may be the same or less than the volume resistivity of the solvent component. In some embodiments, one or more solutes have a volume resistivity 1×10⁸ ohm-m at 25° C. or more, 1×10⁹ ohm-m at 25° C. or more, or even 1×10¹⁰ ohm-m at 25° C. or more.

In some embodiments, one or more solutes can also be selected based on the Hildebrand Solubility Parameter (HSP) of the solute, which is a good measure of the solubility of the solute in a solvent having a similar HSP value (discussed above). In some embodiments, one or more solutes have a Hildebrand Solubility Parameter of 16 or more, 16.5 or more, 17 or more, 18 or more, 19 or more, 20 or more, 25 or more, or even 30 or more.

For multiple solutes, the total solubility of a solvent to a series of solutes can be described in terms of total solubility “S,” which means how much (in terms of weight, molarity (moles of solute), or volume) of the solutes are dissolved in a solvent. At given environmental conditions, the total solubility of a solvent to a series of solvents can be expressed by the following formula:

$$S = f ( a {X}_{1} + b {X}_{2} + c {X}_{3} … ) ,$$

where a, b, and c are coefficients for solutes X₁, X₂, X₃, respectively. The coefficients are relative numbers and depend on the chemical affinity between the solute molecules and the solvent molecules. The coefficients can be determined experimentally for a group of solutes with respect to a specific solvent. X₁, X₂, X₃ refer to the HSP of each solute. When selecting a solute, the HSP of the solute can be similar to the HSP of a specific solvent.

When selecting the Hildebrand Solubility Parameter for a solute, one or more factors in addition to those discussed above (e.g., electrical properties such as dielectric constant) can be considered. For example, in some embodiments, a solute can be selected so that the viscosity of the heat-transfer liquid solution does not increase to an undue degree after combining the solvent component and solute component because an increase in viscosity will cause more pumping power consumption during immersion cooling. As another example, in some embodiments, one or more solutes can be selected to increase the heat capacity of the heat-transfer liquid solution after combining the solvent component and solute component, which means that the heat-transfer liquid solution will have less temperature increase after absorbing the heat generated by electronic components, which corresponds to a lower pumping rate and lower power consumption.

In some embodiments, a solute selected as a pre-existing solute can be the same as the material that is identified to be inhibited from being extracted as described herein.

In some embodiments, a solute selected as a pre-existing solute can be different from one or more materials that are identified to be inhibited from being extracted as described herein. In such a case, it may be desirable to select a solute as a pre-existing solute that has a better chemical affinity to one or more solvents than one or more materials that are identified to be inhibited from being extracted (e.g., from HDDs and/or immersion cooling equipment). A solute having a relatively higher chemical affinity for a given solvent as compared to a material that is identified to be inhibited from being extracted tends to have a higher solubility (a relatively higher amount of selected solute can be dissolve in the solvent as compared to the material that is inhibited from being extracted).

A variety of solutes that can used with a solvent component as described herein can be used in a solute component according to the present disclosure. Non-limiting examples of solutes include one or more solutes chosen from at least one silicone material (e.g., low molecular weight silicone, silicone varnish, silicone rubber), decane, dodecane, glycerol phthalate, polystyrene terephthalate, dimethyl polysiloxane, dioctyl phthalate, one or more nitrile compounds, polyethylene, polyurethane, hexanedioic acid bis (2-ethylhexyl) ester (DEHA), bis (2-ethylhexyl) terephthalate (DEHP), dibutyl phthalate (DBP), didecan-2-yl phthalate, tri (2-Ethylhexyl) trimellitate, neoprene, and combinations thereof. In some embodiments, a solute can be a material that is expected to be different than a potential extracted material from a liquid immersion cooling system and/or an electronic data storage device. Non-limiting examples of such solutes include one or more solutes are chosen from polypropylene (PP), polyamide, polyethylene terephthalate, polyisoprene, one or more siloxanes, and combinations thereof.

A heat-transfer liquid solution according to the present disclosure can be made by combining a solute component with a solute component to form a heat-transfer liquid solution.

Because a heat-transfer liquid solution is mostly made up a solvent component as described herein, a heat-transfer solution can be formulated based on the one or more factors discussed above with respect to selecting a solvent component.

The relative amount of the solvent component and the solute component can vary depending on the factors discussed above including the particular identity of the selected one or more solvents and one or more solutes. For example, one or more solutes can be added in an amount that is similar to the same to materials that would otherwise be “extracted,” as discussed above. In some embodiments, the amount of solute component that is present in a solvent component (e.g., single solvent) can be described in terms of a “solubility ratio.” For a single solute and single solvent, the solubility ratio is the percentage of the amount by weight of solute that is dissolved with the amount by weight of the solvent. For a mixture of two or more solutes in a single solvent, the solubility ratio is the weight percentage of the total amount of the solutes that is dissolved with the amount by weight of the solvent. In some embodiments, a heat-transfer liquid solution has a solubility ratio from 0.1 to 20, or even from 0.5 to 10 at a temperature in a range from 25° C. to 60° C. The amount of solute component that is present in a solvent component can also be described in terms of the weight ratio of solute component to solvent component. In some embodiments, the weight ratio of solute component to solvent component be 1:5 or less, 0.5:5 or less, 0.25:5 or less, 0.1:5 or less, or even 0.05:5 or less at a temperature in a range from 25° C. to 60° C.

In some embodiments, the amount of solute component that is present in a solvent component (e.g., single solvent) can be can be described in terms of the percent saturation a solute in the solvent component. A heat-transfer liquid solution that is 100% saturated means that the maximum amount of a solute has been dissolved into the solvent. Adding additional solute to a saturated heat-transfer liquid solution will not change the concentration of the saturated heat-transfer liquid solution, and the additional solute will remain in the solid phase and typically settle (e.g., to the bottom of a container). So the amount of solute in a 100% saturated solution can be reported in terms of the total weight of solute that dissolves in the solvent at a given temperature. If less solute is present than saturation, then the heat-transfer liquid solution is unsaturated, which can be reported in terms of a percentage less than 100 of saturation. In some embodiments, a solute is present in an amount of greater than 20% saturation, greater than 50% saturation, greater than 80% saturation, greater than 85% saturation, or even greater than 90% saturation at one or more operating temperatures of a system configured to immerse a data storage device in the heat-transfer liquid solution. If the heat-transfer liquid solution includes a single solute as a “pre-existing” solute in the solute component, the solute may be present in an amount that is saturated or near-saturated condition with respect to the lowest cooling temperature that is expected to be encountered in an immersion cooling system. This helps prevent precipitation of the preexisting solute. Similarly, if the heat-transfer liquid solution includes two or more different solutes in the solute component, the total concentration of the solutes can be saturated or slightly lower than the saturation with respect to the lowest cooling temperature that is expected to be encountered in an immersion cooling system. Non-limiting examples of such operating temperatures include a temperature in a range from 0° C. to 70° C., 0° C. to 65° C., or even 5° C. to 60° C.

One or more solutes can be combined with one or more solvents under conditions to that the one or more solutes go into solution and form a heat-transfer liquid solution. For example, the one or more solutes can be added or dispensed while stirring the solvent component. As another example, especially for solvents having relatively low volatility at room temperature, such as mineral oil or synthetic oil solvents, the solvents can be heated to a temperature well below its boiling point to speed up the dissolution process.

For solid solutes, the solid solute can be provided as solid particles that have a size sufficiently small to facilitate dissolving into the solvent component. Liquid solutes can be dispensed into a liquid solvent component in any desired manner.

In some embodiments, the heat-transfer solution can be processed prior to using it as a heat-transfer solution in an immersion cooling system. For example, the heat-transfer solution can be filtered and/or decanted to separate undissolved solid solute from the heat-transfer liquid solution. As another example, any moisture that may be present can be removed from the heat-transfer solution using, e.g., a drying filter.

A heat-transfer liquid solution according to the present disclosure can be used as a single-phase heat-transfer liquid solution in an immersion-cooling system configured to immerse one or more data storage devices in the heat-transfer liquid solution. A non-limiting example will be described by reference to FIG. 5. FIG. 5 shows a an immersion-cooling system 500 that includes a housing 501 having an interior space that can be filled with heat-transfer liquid solution 505 to a liquid level 506 that permits a plurality of data storage devices 503 to be completely submerged in the heat-transfer liquid solution 505 while the data storage devices are electrically energized. For example, the data storage devices can include sealed hard disk drives, which do not allow the heat-transfer liquid solution 505 to penetrate to the interior of the sealed hard disk drives.

While the data storage devices 503 are operating via electrical power, heat is generated and transferred to heat-transfer liquid solution 505. The heated heat-transfer liquid solution 508 can be pumped via pump system 510 from housing 501 to a heat-exchanger 520 to cool the heat-transfer-liquid solution and return the cooled heat-transfer liquid solution 512 to the housing 501. As shown, heat-exchanger 520 can use chilled water system 530 to provided chilled water 532 to heat-exchanger 520 and remove heat from heat-exchanger 520 via line 534.

1. A method of making a heat-transfer liquid solution, wherein the method comprises:
providing a heat-transfer liquid comprising a solvent component, wherein the solvent component comprises one or more solvents, and wherein each solvent has a dielectric constant; and
combining the heat-transfer liquid with a solute component to form a heat-transfer liquid solution, wherein the solute component comprises one or more solutes, and wherein each solute has a dielectric constant, and wherein the heat-transfer liquid solution has a dielectric constant of 7.5 or less at a frequency of 1 khz and a temperature in a range from 0° C. to 60° C.

2. The method of claim 1, the heat-transfer liquid solution has a dielectric constant of 3 or less at a frequency of 1 khz and a temperature in a range from 0° C. to 60° C.

3. The method of claim 1, wherein the dielectric constant of each solute is equal to or less than the dielectric constant of each solvent at one or more operating temperatures of an immersion-cooling system configured to immerse one or more data storage devices in the heat-transfer liquid solution.

4. The method of claim 1, wherein the solvent component comprises one or more solvents chosen from one or more hydrocarbon solvents, one or more fluorocarbon solvents, one or more hydrofluorocarbon solvents, and combinations thereof.

5. The method of claim 1, wherein the solvent component comprises one or more solvents chosen from at least one natural oil, at least one synthetic oil, at least one fluoro-octane, at least one hydrofluoroether, at least one hydrofluorolefin, at least one perfluoroketone, at least one perfluoropolyether, at least one perfluorocarbon, and mixtures thereof.

6. The method of claim 1, wherein each solvent and each solute has a Hildebrand Solubility Parameter of 16.5 or more.

7. The method of claim 1, wherein the solute component has a solubility ratio from 0.1 to 20 at a temperature in a range from 25° C. to 60° C.

8. The method of claim 1, wherein the solute component comprises one or more solutes chosen from at least one silicone material, decane, dodecane, glycerol phthalate, polystyrene terephthalate, dimethyl polysiloxane, dioctyl phthalate, one or more nitrile compounds, polyethylene, polyurethane, hexanedioic acid bis (2-ethylhexyl) ester (DEHA), bis (2-ethylhexyl) terephthalate (DEHP), dibutyl phthalate (DBP), didecan-2-yl phthalate, tri (2-Ethylhexyl) trimellitate, neoprene, and combinations thereof.

9. The method of claim 1, wherein at least one solute is present in a weight ratio solute:solvent component of 1:5 or less.

10. The method of claim 1, wherein each solvent has a dielectric constant of 7.5 or less at a frequency of 1 khz, and wherein each solute has a dielectric constant of 7.5 or less at a frequency of 1 khz.

11. (canceled)

12. (canceled)

13. The method of claim 1, wherein the solvent component has a volume resistivity greater than 1×10⁸ ohm-m at 25° C.

14. The method of claim 1, wherein combining the heat-transfer liquid with the solute component to form the heat-transfer liquid solution comprises adding one or more solid solutes to the heat-transfer liquid so that at least a portion of the one or more solid solutes dissolve to form the heat-transfer liquid solution.

15. The method of claim 14, further comprising filtering the heat-transfer liquid solution to remove undissolved solid solute.

16. The method of claim 14, further comprising removing water from the heat-transfer liquid solution.

17. The method of claim 1, wherein combining the heat-transfer liquid with the solute component to form the heat-transfer liquid solution comprises dispensing one or more liquid solutes to the heat-transfer liquid to form the heat-transfer liquid solution.

18. The method of claim 17, further comprising removing water from the heat-transfer liquid solution.

19. The method of claim 1, wherein the heat-transfer liquid solution is used as a single-phase heat-transfer liquid solution in an immersion-cooling system configured to immerse one or more data storage devices in the heat-transfer liquid solution.

20. The method of claim 19, wherein the one or more data storage devices comprise a plurality of sealed hard disk drives, and wherein the heat-transfer liquid solution is a single-phase heat-transfer liquid solution having a boiling point of 100° C. or more, and further comprising:
filling the immersion-cooling system with the heat-transfer liquid solution;
submerging the plurality of sealed hard disk drives in the heat-transfer liquid solution;
applying electrical power to the plurality of sealed hard disk drives at least partially while the plurality of sealed hard disk drives are submerged in the heat-transfer liquid solution; and
circulating the heat-transfer liquid solution through the immersion-cooling system to transfer heat from the plurality of sealed hard disk drives to the heat-transfer liquid solution.

21. A method of making a heat-transfer liquid solution, wherein the method comprises.
providing a heat-transfer liquid comprising a solvent component, wherein the solvent component comprises one or more solvents, and wherein each solvent has a dielectric constant; and
combining the heat-transfer liquid with a solute component to form a heat-transfer liquid solution, wherein the solute component comprises one or more solutes, and wherein each solute is present in an amount of greater than 20% saturation at one or more operating temperatures of a system configured to immerse a data storage device in the heat-transfer liquid solution.

22. (canceled)

23. (canceled)

24. A heat transfer liquid solution comprising:
a solvent component comprising one or more solvents; and
a solute component comprising one or more solutes, wherein the one or more solutes are chosen from polypropylene, polyamide, polyethylene terephthalate, polyisoprene, one or more siloxanes, and combinations thereof.

25.-27. (canceled)
